(19) United States
(12) Patent Application Publication
(10) Pub. No.: US 2025/0322110 A1
(43) Pub. Date: Oct. 16, 2025

(54) DEGREE LAYOUT DESIGN of ALPHA-NUMERIC, SYMBOLISTIC AND/OR PICTORIAL MANUFACTURE for MULTIPLE USERS OR VIEWERS

(71) Applicant: MARVIN CHAMBERS, CARRBORO, NC (US)

(72) Inventor: MARVIN CHAMBERS, CARRBORO, NC (US)

(21) Appl. No.: 18/636,342

(22) Filed: Apr. 16, 2024

(51) Int. Cl. G06F 30/12

(52) U.S. Cl. CPC G06F 30/12

(57) ABSTRACT

The Degree Layout Design for alphabetical, numerical, alpha-numeric and/or symbolistic pictorializing can allow multiple users or interpreters the ability to utilize or interpret the same article of manufacture, simultaneously, without requiring the users/interpreters themselves, to rotate the article of manufacture. For smartphones, and some laptops, such a feature may be called, auto-rotate, but such a feature is not specifically designed for non-software based articles of manufacture, and where it is, such a feature is limited to what I call for my invention, zero (0) degree eye-parallel versus ninety (90) degree rotation. Essentially, this form of rotation is from landscape viewing to portrait viewing, or vice versa. My Degree Layout Design for alphabetical, numerical, alpha-numeric and/or symbolistic pictorializing allows this innovative tech-savvy concept to exist as landscape to landscape, portrait to portrait, portrait to landscape, and/or landscape to portrait, with essentially no limit in degree(s), with regard to every other article of manufacture, digital and analogue, where available, and not previously assigned, without limitation.

### CROSS-REFERENCE TO RELATED APPLICATIONS

At the filing date of this application, it is believed that no cross-reference of prior art can be made to my invention, as it is not believed that there is a patent for such interpretative alphabetical, numerical, or alpha-numeric, symbolistic, and/or pictorial material of eye-parallel zero (0) degree material, or that such a patent was issued to date, or that such a patent does or would expressly be limited to one user or interpreter, or conversely, expressly intend use for multiple users or interpreters. The foregoing stated, my invention alters the fixed degree of interpretative alphabetical, numerical, or alpha-numeric, symbolistic, and/or pictorial material, for manufacture, from zero (0) degree, which accounts for a fixed eye-parallel level, to varying degrees that include any degree from one to three hundred fifty-nine (1-359) degrees, to allow multiple interpreters of word and/or pictorial material, to use the same material simultaneously, without exclusion of alternate symbolisms. Further, to the extent that there is no definition for eye-parallel interpretation of word and/or pictorial material, at zero (0) degree, specificity, my claim for patent includes such zero (0) degree manufacture for/of interpretation of alphabetical, numerical, or alpha-numeric, symbolistic, and/or pictorial material, and/or the inclusion of three hundred sixty (360) degree manufacture for/of the same.

### BACKGROUND OF THE INVENTION

At the filing date of this application, it is believed that no specific cross-reference of prior art can be made to my invention. That said, my invention comes from a need to enhance paraphernalia, book, and other interpretive materials to be used by multiple persons/interpreters, simultaneously. My invention achieves this, by having multiple versions of the interpretive material on the same panel, page, manufacture, etc., and then altering the layout of some or all unspecified set of material for interpretation, to varying fixed degrees on the manufacture, or manufactured product, or product of manufacture, so that multiple users may position themselves around the article of manufacture, as though the article were from a fixed position, rather than the article of manufacture needing to be rotated, to some interpreter's fixed eye position.

### BRIEF SUMMARY OF THE INVENTION

My Degree Layout Design for alphabetical, numerical, alpha-numeric, symbolistic and/or other pictorializing, is an article of manufacture that can be shared, interpreted, viewed, etc., for use and/or interpretation, etc., by multiple users/interpreters, simultaneously, with varying angles of/for parallel viewership, reduces the need to clamor around the same article, with only one layout degree for interpretive engagement, especially when the article of manufacture is small. This also reduces the need to buy multiple one pieces, of the same manufacture, which makes sharing, collaboration, collaborative study, and collaborative interpretation, all, easier, and enhances the teaching and learning process, through the article of manufacture, to be more specific, specialized, and guided. As an added benefit, my Degree Layout Design may very well limit or end the need for such terms as right-side-up, and upside-down.

### BRIEF DESCRIPTION OF DRAWINGS

FIG. 1 is a top plan view of left and right reading panels for two (2) users of the same material, with one user on the right, and another on the left, and vertically across from each. FIG. 1, shows an interpretative layout set to be offset by one hundred eighty (180) degrees, from the other set.

FIG. 2 is a top plan view of left and right panels for four (4) users of the same material, with one user on the right, another user across horizontally on the left, and two participants in the middle, positioned across from each other, along the vertical axis of the article of manufacture's top, and bottom, respectively. FIG. 2, shows double the interpretative layout set as FIG. 1, being offset at one hundred eighty (180) degrees, each, from two other layout sets, where one of these layout sets is shown at either zero (0) degree, or three hundred sixty (360) degrees, another layout set is shown at one hundred eighty (180) degrees, an additional layout set is shown at ninety (90) degrees, and, in this case, a final layout set is shown at two hundred seventy (270) degrees.

FIG. 3 is a top plan view of left and right panels that allow three (3) users for the same material, with two users at either end of a material's top and bottom vertical axis (one at ninety (90) degrees, and another at two hundred seventy (270) degrees), and a third user's, possibly teacher's layout set along one of the material's horizontal edges at one hundred eighty (180) degrees; which, perpendicular area, can be for demonstration, training, teaching, etc.

### DETAILED DESCRIPTION OF THE INVENTION

Step 1: Add any combination of alphabetical, numeric, alpha-numeric, symbolistic, or other pictorial expression on a panel of manufacture.

Step 2: Rotate the. expression a full three hundred sixty (360) degrees.

Step 3: This is a layout set.

Step 4: Add a second combination of alphabetical, numeric, alpha-numeric, symbolistic, or other pictorial expression onto the same panel of manufacture.

Step 5: Rotate this second expression to a different degree than the previous expression.

Step 6: This is another layout set.

Step 7: Add as many combination set(s) at varying degrees as desired, thus making as many layout sets as desired.

Step 8: When done, process the manufacture for use, consumption, distribution, and/or distributive use, for and/or by desired number of interpreters, or users.

Step 9: When necessary, and only if necessary, the panels may be connected together, by binding, sewing, adhering, stapling, pasting, gluing, or any of various combining or blending methodology of/for manufacture, without limitation, including nailing, soldering, welding, etc.

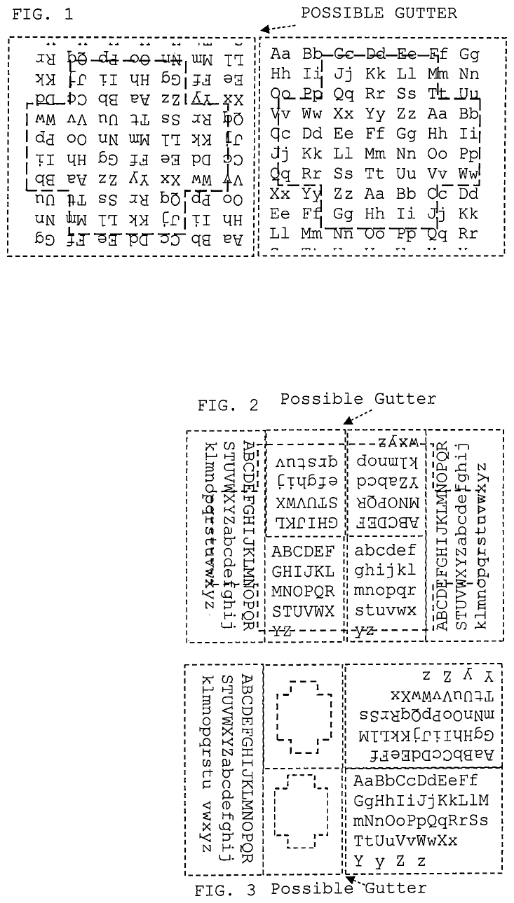

I, Marvin Chambers, have invented a layout design for multiple-interpreters of word and/or pictorial manufacture, as set forth in the following specification. The claimed layout design is set forth in a way to allow multiple readers and/or pictograph interpreters to use the same reading material simultaneously, by changing the layout degree, to the desired degree for access, i.e. from prior art standard of fixed eye-parallel 0 degree to fixed layout positions of 90, 180, 270, or 360 degrees without degree limitation. FIG. 1 is a top plan view of left and right reading panels for two (2) users of the same material, with one user on the right, and another on the left, and vertically across from each.

FIG. 2 is a top plan view of left and right panels for four (4) users of the same material, with one user on the right, another user across horizontally on the left, and two participants in the middle, positioned across from each other, along the material's vertical axis.

FIG. 3 is a top plan view of left and right panels that allow three (3) users for the same material, with two users at either end of a material's top and bottom vertical axis, and a third user/teacher along one of the material's horizontal edges; which, perpendicular area, can be for demonstration, training, teaching, etc. More reader versions are possible and interchangeable, and can be based, in part, on the configurations shown. Dotted, picture-graphs in Top Plan Views are for illustrative purposes only, to show possible areas for graphs or illustrations. Lines on panels show manufacture edges, gutter and sheet proportion and congruency. Sizes, number of panels, or arrangements need not be viewed as fixed. Such as those shown in broken lines, are for illustrative purposes only and form no part of the claimed design. I claim the Degree Layout Design for alpha-numeric, symbolistic and/or other pictorializing from multiple angles and can allow multiple users or viewers the ability to simultaneously use the same interpretive material, manufacture, etc., as shown.

1. I claim the Degree Layout Design for alphabetical, numerical, alpha-numeric, symbolistic and/or other pictorializing, that presents such character(s), symbol(s), and/or pictograph(s), without limitation or exclusion, from multiple angles of degrees from 0.000000001 degrees to 359.999999999 degrees, and can allow multiple users/interpreters the ability to simultaneously use the same interpretative material, book, manufacture, etc., as shown.

2. I claim the Degree Layout Design for alphabetical, numerical, alpha-numeric and/or symbolistic pictorializing, that presents such character(s), symbol(s), and/or pictograph(s), without limitation or exclusion, from multiple angles of degrees including three hundred sixty (360) degrees, where the article of manufacture is first rotated clockwise, counterclockwise, or need no prior rotation, and can allow multiple users/interpreters the ability to simultaneously use the same interpretive material, book, manufacture, etc., as shown.

3. I claim the Degree Layout Design for alphabetical, numerical, alpha-numeric and/or symbolistic pictorializing, that presents such character(s), symbol(s), and/or pictograph(s), without limitation or exclusion, from multiple angles of degrees including zero (0) degree, where such definition for layout design of, for, with, through, by, and in alphabetical, numerical, alpha-numeric and/or symbolistic pictorializing, by, in, with, and through degree(s), or a degree system is non-existent, as shown.
